(19) United States
(12) Patent Application Publication
(10) Pub. No.: US 2026/0018567 A1
(43) Pub. Date: Jan. 15, 2026

(54) PACKAGE DEVICE AND MANUFACTURING METHOD THEREOF

(71) Applicant: POWERTECH TECHNOLOGY INC., HSINCHU COUNTY (TW)

(72) Inventors: Shang-Che Tsai, HSINCHU COUNTY (TW); Shang-Yu Chang Chien, HSINCHU COUNTY (TW)

(73) Assignee: POWERTECH TECHNOLOGY INC., HSINCHU COUNTY (TW)

(21) Appl. No.: 19/334,940

(22) Filed: Sep. 21, 2025

Related U.S. Application Data
(63) Continuation-in-part of application No. 17/994,409, filed on Nov. 28, 2022.

(30) Foreign Application Priority Data
Mar. 2, 2022 (TW) 111107443

(51) Int. Cl. H01L 25/07; H01L 23/00; H01L 23/31; H01L 23/34; H01L 23/498; H01L 23/538; H01L 25/00

(52) U.S. Cl. CPC H01L 25/071; H01L 23/3107; H01L 23/34; H01L 23/49811; H01L 23/5385; H01L 23/5389; H01L 24/24; H01L 25/50; H01L 2224/244

(57) ABSTRACT

A package device and a manufacturing method thereof are provided. The package device includes a package structure, a redistribution layer, an underfill layer, a plurality of conductive pillars, another redistribution layer, and an encapsulant. The underfill layer is disposed between the package structure and the redistribution layer, and the conductive pillars and the package structure are disposed side by side between the redistribution layers. The encapsulant is disposed between the redistribution layers and surrounds the package structure and the conductive pillars.

### CROSS REFERENCE TO RELATED APPLICATIONS

This application is a continuation-in-part of U.S. application Ser. No. 17/994,409, filed on Nov. 28, 2022. The content of the application is incorporated herein by reference.

### BACKGROUND OF THE INVENTION

### 1. Field of the Invention

The present invention relates to a package device and a manufacturing method thereof, and particularly to a package device including stacked and coupled chips and a manufacturing method thereof.

### 2. Description of the Prior Art

Recently, in order to integrate various functions to meet customer requirements, it has been developed to encapsulate multiple active chips in the same package device. However, as the active chips have more functions or higher computing power, the requirements for interconnection structures between the active chips is higher. For this reason, to improve the interconnection efficiency between the active chips and reduce manufacturing cost and manufacturing complexity of the package device is an objective in this field.

### SUMMARY OF THE INVENTION

An embodiment of the present invention provides a package device including a package structure, a second redistribution layer, a first underfill layer, a plurality of second conductive pillars, a third redistribution layer, and a second encapsulant. The package structure includes a plurality of first conductive pillars disposed side by side, a first redistribution layer, at least two first chips, at least one second chip, and a first encapsulant. The first redistribution layer is disposed on the first conductive pillars, the first chips are disposed on the first redistribution layer, and the second chip is disposed under the first redistribution layer, wherein the second chip is coupled to the first chips through the first redistribution layer. The first encapsulant is disposed on the first redistribution layer and surrounds the first chips. The package structure is disposed on the second redistribution layer, and the second chip is located between the first redistribution layer and the second redistribution layer. The first underfill layer is disposed between adjacent two of the first conductive pillars and between one of the first conductive pillars and the second chip. The second conductive pillars are disposed on the second redistribution layer and side by side with the package structure. The third redistribution layer is disposed on the package structure and the second conductive pillars, and the second encapsulant is disposed between the second redistribution layer and the third redistribution layer and surrounds the package structure and the second conductive pillars.

Another embodiment of the present invention provides a manufacturing method of a package device including providing a package structure, forming a second redistribution layer on a first carrier, forming a plurality of second conductive pillars on the second redistribution layer, disposing the package structure on the second redistribution layer, forming a second encapsulant on the second redistribution layer, forming a third redistribution layer on the second conductive pillars and the package structure, and removing the first carrier, wherein the second encapsulant surrounds the package structure and the second conductive pillars. The package structure includes a plurality of first conductive pillars disposed side by side, a first redistribution layer, at least two first chips, at least one second chip, and a first encapsulant. The first redistribution layer is disposed on the first conductive pillars, the first chips are disposed on the first redistribution layer, and the second chip is disposed under the first redistribution layer, wherein the second chip is coupled to the first chips through the first redistribution layer. The first encapsulant is disposed on the first redistribution layer and surrounds the first chips.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 schematically illustrate a manufacturing method of a package device according to an embodiment of the present invention.

FIG. 8 schematically illustrates a cross-sectional view of a package device according to another embodiment of the present invention.

FIG. 9 to FIG. 12 schematically illustrate a manufacturing method of a package device according to a third embodiment of the present invention.

FIG. 13 schematically illustrates a cross-sectional view of a package device according to a fourth embodiment of the present invention.

FIG. 14 schematically illustrates a cross-sectional view of a package device according to a fifth embodiment of the present invention.

FIG. 15 schematically illustrates a cross-sectional view of a package device according to a sixth embodiment of the present invention.

### DETAILED DESCRIPTION

The contents of the present disclosure will be described in detail with reference to specific embodiments and drawings. In order to make the contents clearer and easier to understand, the following drawings may be simplified schematic diagrams, and elements therein may not be drawn to scale. The numbers and sizes of the elements in the drawings are just illustrative and are not intended to limit the scope of the present disclosure.

Spatially relative terms, such as “above”, “on”, “beneath”, “below”, “under”, “left”, “right”, “before”, “front”, “after”, “behind” and the like, used in the following embodiments just refer to the directions in the drawings and are not intended to limit the present disclosure. It should be understood that the elements in the drawings may be disposed in any kind of formation known by one skilled in the related art to describe the elements in a certain way.

When one element or layer is referred to as “on” or “above” another element or another layer, it may be understood that the element or layer is “directly on” the another element or the another layer, or other element or other layer may be between them. On the contrary, when one element or layer is “directly on” another element or another layer, it may be understood that there is no element or layer between them.

When an element is referred to as being “electrically connected to” or “coupled to” another element, it may be understood that “other element may be between the element and the another element and electrically connects them to each other”, or “there are no intervening elements present between the element and the another element, and the element and the another element are directly electrically connected to each other”. When an element is referred to as being “directly electrically connected to” or “directly coupled to” another element, there are no intervening elements present between the element and the another element, and the element and the another element are directly electrically connected to each other.

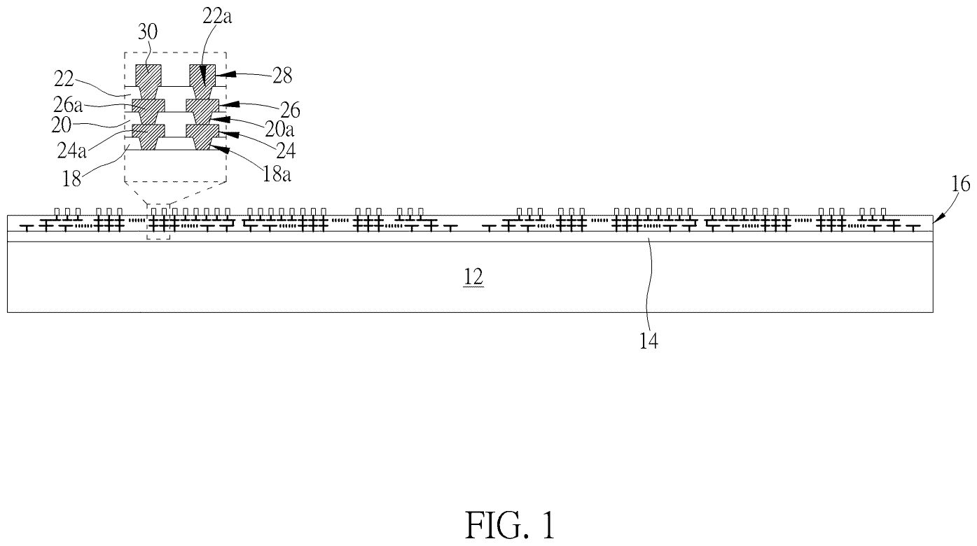

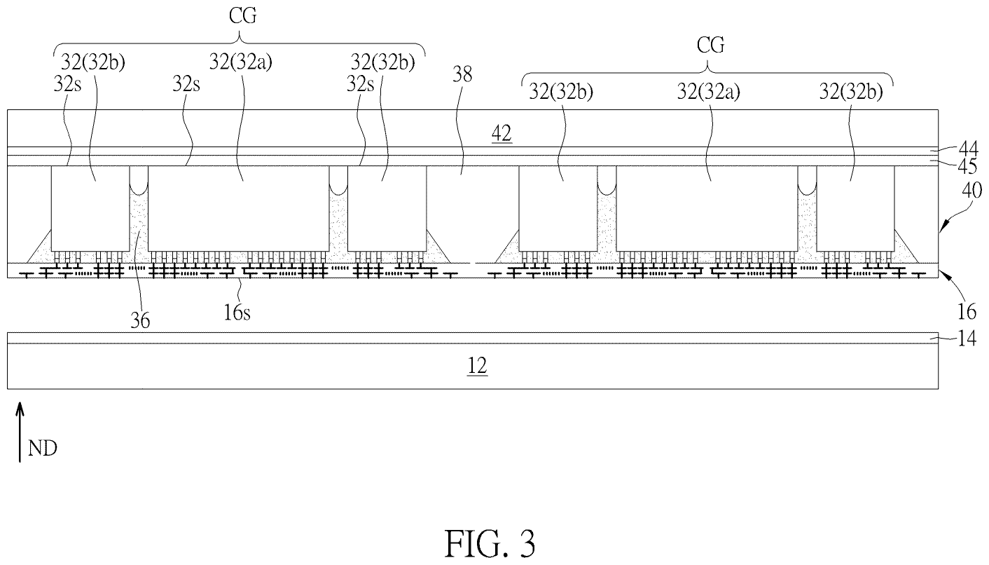

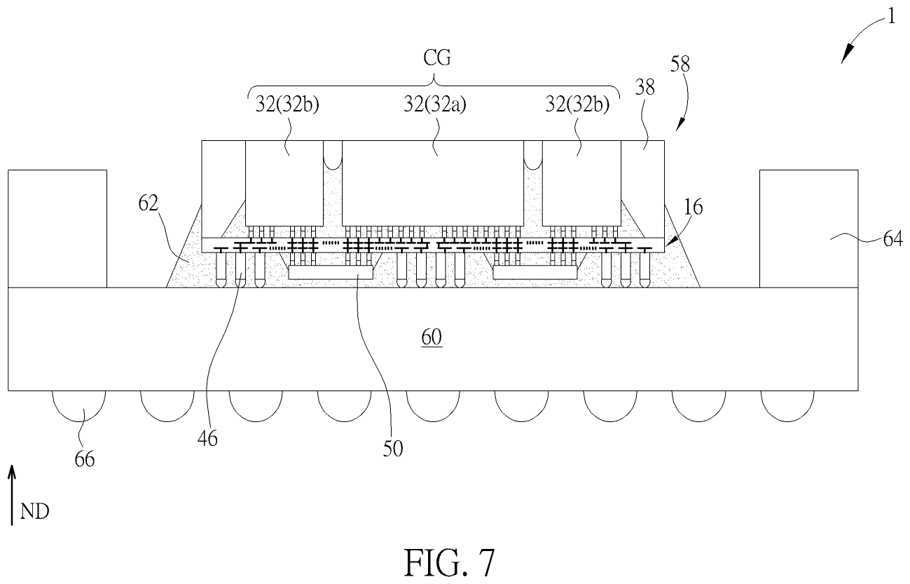

Please refer to FIG. 1 to FIG. 7. FIG. 1 to FIG. 7 schematically illustrate a manufacturing method of a package device according to an embodiment of the present invention, and FIG. 7 schematically illustrates a cross-sectional view of the package device according to an embodiment of the present invention. Structures shown in FIG. 1 to FIG. 7 may be partial structures in different steps during manufacturing package devices, and some layers or elements may be omitted, but not limited thereto. As shown in FIG. 1, a carrier 12 is provided first, in which the carrier 12 may have a release layer 14 thereon. Then, a redistribution layer 16 is formed on the release layer 14. The carrier 12 may be used to carry films or elements formed thereon, and the carrier 12 may include, for example, but not limited to, glass, wafer substrate, metal, or other suitable supporting materials. The release layer 14 may be used to separate the carrier 12 from the elements formed thereon (e.g., the package structure 40 shown in FIG. 3) after subsequent steps are completed. The releasing manner of the release layer 14 may include, for example, photo dissociation or other suitable manners. The release layer 14 may, for example, include polyethylene (PE), polyethylene terephthalate (PET), epoxy (epoxy), oriented polypropylene (OPP)) or other materials suitable material, but not limited thereto.

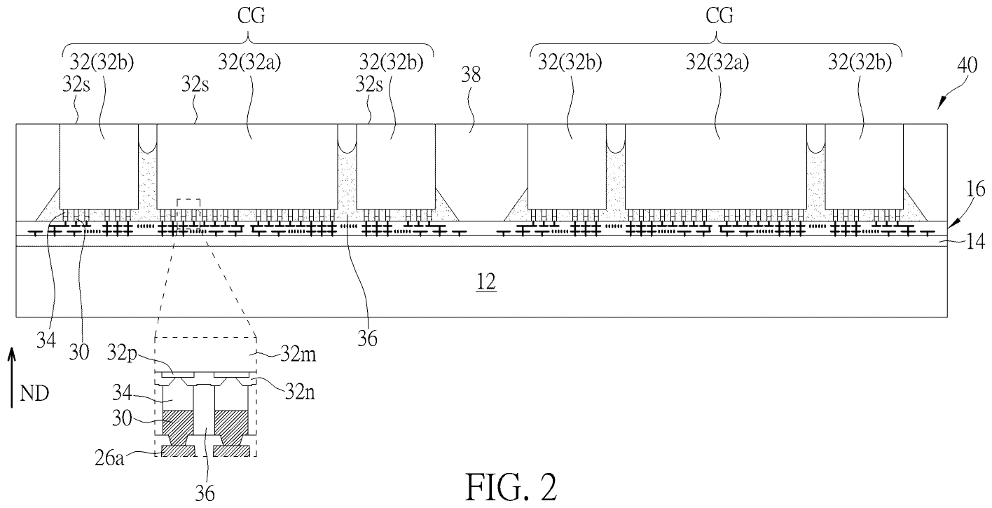

The redistribution layer 16 may include at least one dielectric layer and at least one conductive layer. In the embodiment of FIG. 1, the redistribution layer 16 includes three dielectric layers 18, 20, 22 and three conductive layers 24, 26, 28 as an example, but not limited thereto. The dielectric layer 18, the conductive layer 24, the dielectric layer 20, the conductive layer 26, the dielectric layer 22 and the conductive layer 28 may be sequentially formed on the release layer 14. The dielectric layer 18 may have a plurality of through holes 18a, and the conductive layer 24 may be disposed on the dielectric layer 18 and may include a plurality of traces 24a extending into the through holes 18a. The dielectric layer 20 may be disposed on the conductive layer 24 and may have a plurality of through holes 20a exposing the corresponding traces 24a. The conductive layer 26 may be disposed on the dielectric layer 20 and may include a plurality of traces 26a extending into the through holes 20a, for being coupled to the corresponding traces 24a. The dielectric layer 22 may be disposed on the conductive layer 26 and may have a plurality of through holes 22a. The conductive layer 28 may include a plurality of conductive bumps 30 disposed on the dielectric layer 22 and respectively disposed in the corresponding through holes 22a, for being electrically connected to the corresponding traces 26a. The conductive layers of the redistribution layer may be formed by an electroplating process or other suitable processes. The formation of the conductive bumps 30 may facilitate bonding and coupling with active chips disposed in subsequent step (e.g., active chip 32 in FIG. 2). The conductive bump 30 may include, for example, a multi-layer structure. The multi-layer structure may include, for example, copper, nickel, gold, other suitable materials, or a combination thereof, but not limited thereto. In some embodiments, the number of the conductive layers and the number of the dielectric layers may be adjusted according to the requirements.

It should be noted that since the redistribution layer 16 may be formed on a flat surface of the release layer 14 (or the carrier 12) before other elements are formed on the release layer 14 (or the carrier 12), the manufacturing complexity of the redistribution layer 16 may be reduced, thereby decreasing a trace pitch (e.g., fine pitch) of the same conductive layer in the redistribution layer 16. The trace pitch of a conductive layer may for example refer to a sum of a trace width (or line width) of the conductive layer and a space (or a distance) between two adjacent traces (or lines) of the conductive layer. For example, the trace width and/or the space between two adjacent traces of the redistribution layer 16 may be 2 micrometers (μm) to 10 micrometers.

As shown in FIG. 2, after the redistribution layer 16 is formed, at least two chips 32 may be disposed on the redistribution layer 16. In the embodiment of FIG. 2, the number of chips 32 may be plural, and the chips 32 may be divided into at least two chip groups CG respectively corresponding to package devices to be formed (e.g., the package device 1 as shown in FIG. 7), but not limited to this.

In the embodiment of FIG. 2, each chip 32 may, for example, include a plurality of conductive bumps 34 to facilitate bonding with the redistribution layer 16, but not limited thereto. For example, one of the chips 32 may further include a body portion 32m, a plurality of input/output pads 32p, and an insulating layer 32n, in which the input/output pads 32p may be disposed between the body portion 32m and the insulating layer 32n, and the insulating layer 32n has a plurality of openings exposing corresponding input/output pads 32p. The conductive bumps 34 may be formed on the corresponding input/output pads 32p, respectively. In addition, the conductive bumps 34 of the chip 32 may be bonded to the corresponding conductive bumps 30 of the redistribution layer 16 in a face-down way through a flip-chip bonding process, so that the chip 32 may be coupled to the redistribution layer 16. Metal solder (not shown) may be included between one of the conductive bumps 34 and the corresponding conductive bump 30, for bonding the conductive bump 34 to the corresponding conductive bump 30. The metal solder may include, for example, tin alloy solder or other suitable materials, but not limited thereto.

The chip 32 may be, for example, an active chip or other suitable chips. The active chip may include, for example, a power management integrated circuit (PMIC) chip, a micro-electro-mechanical-system (MEMS) chip, an application-specific integrated circuit chip (ASIC), a dynamic random access memory (DRAM) chip, a static random access memory (SRAM) chip, a high bandwidth memory (HBM) chip, a system chip (SoC), a high performance computing (HPC) chip, a chiplet, or other suitable chip, but not limited thereto. In the embodiment of FIG. 2, one of the chip groups CG may include chips 32a, 32b having the same characteristic or different characteristics. When the chip 32a and the chip 32b have different characteristics, the chip 32a and the chip 32b may be, for example, a system chip and a high bandwidth memory chip, respectively, but not limited thereto. For example, one chip group CG may include one chip 32a and four chips 32b, but not limited thereto. The chip 32 mentioned herein may refer to a chip including an active element, and the active element may include a transistor, a diode, an integrated circuit, an optoelectronic element, or other suitable elements with gain, but not limited thereto. The chip may also be referred to as a die, but is not limited thereto. The term “coupling” may also be referred to as “electrically connecting”, but not limited thereto. The conductive bump 34 may, for example, include a multi-layer structure. The conductive bump 34 may include, for example, copper, nickel, tin, silver, other suitable materials, alloys of at least two of the foregoing, or a combination thereof, but not limited thereto.

In some embodiments, since the redistribution layer 16 may be formed before the chips 32 are disposed, an automated optical inspection (AOI) and/or an open/short test (O/S test) may be optionally performed on the redistribution layer 16 before the chips 32 are disposed, so as to ensure quality of the redistribution layer 16. Accordingly, chip loss or waste caused by defect of the redistribution layer 16 may be avoided or reduced. In some embodiments, the automated optical inspection and/or the open/short test may be performed after the redistribution layer 16 is completed or repeated multiple times during the formation of the redistribution layer 16.

As shown in FIG. 2, after the chips 32 are disposed, an encapsulant 38 may be formed on the redistribution layer 16 to form a semi-finished structure 40, in which the encapsulant 38 may at least laterally surround the chips 32 to protect the chips 32 and the bonding between the chips 32 and the redistribution layer 16. For example, the encapsulant 38 may be formed between the chips 32 and on the back surfaces 32s of the chips 32 through a molding process to seal the chips 32 on the redistribution layer 16. The encapsulant 38 may include, for example, a molding compound or other suitable encapsulating materials, but not limited thereto.

It should be noted that, since the redistribution layer 16 that is thinner than the carrier 12 is first formed on the rigid carrier 12 instead of being first formed on the encapsulant 38, the redistribution layer 16 does not have obvious warping resulted from structure shrinkage or expansion. Accordingly, when the chips 32 are bonded to the redistribution layer 16, there is no need to compensate pattern position shift of the redistribution layer 16 caused by the structure shrinkage or expansion, thereby improving manufacturing efficiency. For example, the pattern position shift of the redistribution layer 16 may refer to change of relative positions between bonding pads due to the structure shrinkage or expansion when the redistribution layer is formed on the encapsulant first, so that the flip-chip bonding process of chips needs to compensate the pattern position shift.

In some embodiments, a thinning process may be optionally performed on the encapsulant 38 to remove a portion of the encapsulant 38 located on the chips 32 and expose the back surfaces 32s of the chips 32, thereby facilitating the heat dissipation of the chips 32. The thinning process may include, for example, a chemical mechanical polishing (CMP) process, a mechanical grinding process, an etching process or other suitable processes, but not limited thereto.

In some embodiments, as shown in FIG. 2, between the step of disposing the chips 32 on the redistribution layer 16 and the step of forming the encapsulant 38, an underfill layer 36 may be optionally filled between the chips 32 and the redistribution layer 16 to strengthen the bonding between the chips 32 and the redistribution layer 16, thereby reducing break between the conductive bumps 30 and the conductive bumps 34. The underfill layer 36 may include, for example, capillary underfill (CUF) or other suitable filling materials, but not limited thereto. The underfill layer 36 may be formed by, for example, a dispensing process.

As shown in FIG. 3, the semi-finished structure 40 including the redistribution layer 16, the chips 32 and the encapsulant 38 may be transferred to a carrier 42 to expose a surface 16s of the redistribution layer 16 away from the chips 32. For example, after the encapsulant 38 is formed, the back surfaces 32s of the chips 32 and a surface of the encapsulant 38 away from the redistribution layer 16 may be attached to the carrier 42 to reduce warpage of the semi-finished structure 40. For example, a release layer 44 and an adhesive layer 45 may be sequentially disposed on the carrier 42, and the semi-finished structure 40 may be attached to the carrier 42 by the adhesive layer 45, so that the release layer 44 and the adhesive layer 45 may be between the carrier 42 and the chips 32 and between the carrier 42 and the encapsulant 38. The adhesive layer 45 may include a material for carrier bonding. The material of the release layer 44 may be, for example, the same as or similar to the material of the release layer 14 and will not be repeated herein. Then, the carrier 12 is removed. The manner of removing the carrier 12 may include, for example, irradiating the release layer 14 with light to reduce adhesion of the release layer 14, thereby removing the carrier 12, but not limited thereto.

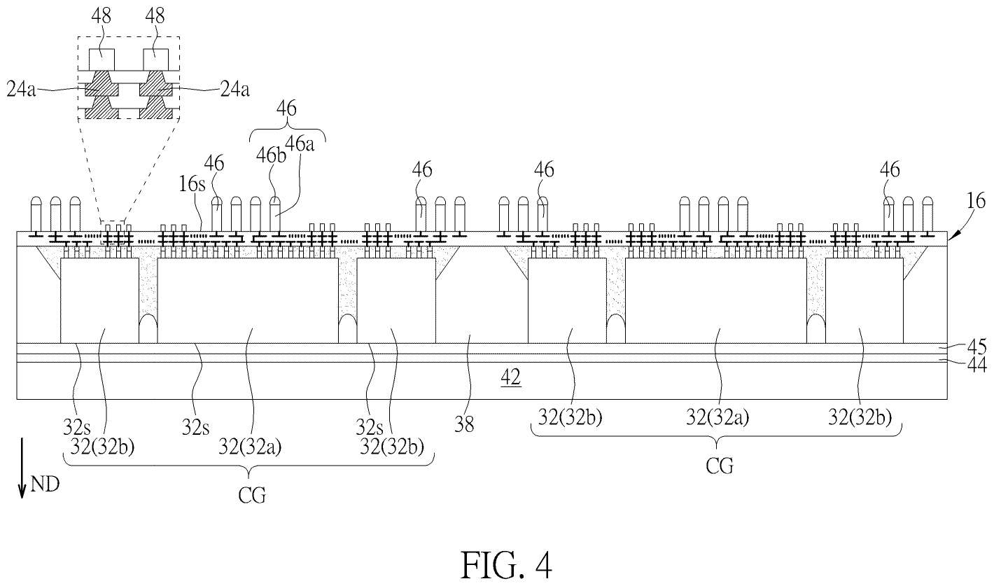

As shown in FIG. 4, the semi-finished structure 40 is then turned upside down, so that the surface 16s of the redistribution layer 16 away from the chips 32 faces upward, and the back surfaces 32s of the chips 32 face downward. Then, a plurality of conductive pillars 46 disposed side by side are formed on the surface 16s of the redistribution layer 16 away from the chips 32, so that each conductive pillar 46 may be coupled to the corresponding trace 24a. Also, the conductive pillars 46 may be coupled to the chips 32 through the redistribution layer 16. The conductive pillars 46 may be formed by, for example, a deposition process combined with a photolithography process and an etching process, an electroplating process combined with an etching process, or other suitable processes. In the embodiment of FIG. 4, one of the conductive pillars 46 may be, for example, a multi-layer structure, but not limited thereto. For example, the conductive pillar 46 may include a pillar portion 46a and a bonding portion 46b. The pillar portion 46a may include, for example, copper, aluminum, nickel, other suitable conductive materials, alloys of at least two thereof, or a combination thereof. The bonding portion 46b may include, for example, a tin-silver alloy, other suitable materials, or a combination thereof, but not limited thereto. The conductive pillar 46 may be, for example, a copper pillar bump (CPB) or other suitable bumps. In this embodiment, since the conductive pillar 46 includes the bonding portion 46b, it may be used for signal connections of the chips or package structure (e.g., package structure 58) with other outer structures, but not limited thereto.

In some embodiments, a plurality of conductive pillars 48 may be optionally formed on the surface 16s of the redistribution layer 16 away from the chips 32 to facilitate bonding with a chip disposed in a subsequent step. The conductive pillars 48 may be coupled to the corresponding chips 32 through the redistribution layer 16. A height of one of the conductive pillars 48 may be less or much less than a height of one of the conductive pillars 46. In some embodiments, the conductive pillars 48 may be formed before or after the step of forming the conductive pillars 46. The conductive pillars 48 may be formed by, for example, a deposition process combined with a photolithography process and an etching process, an electroplating process combined with an etching process, or other suitable processes, but not limited thereto.

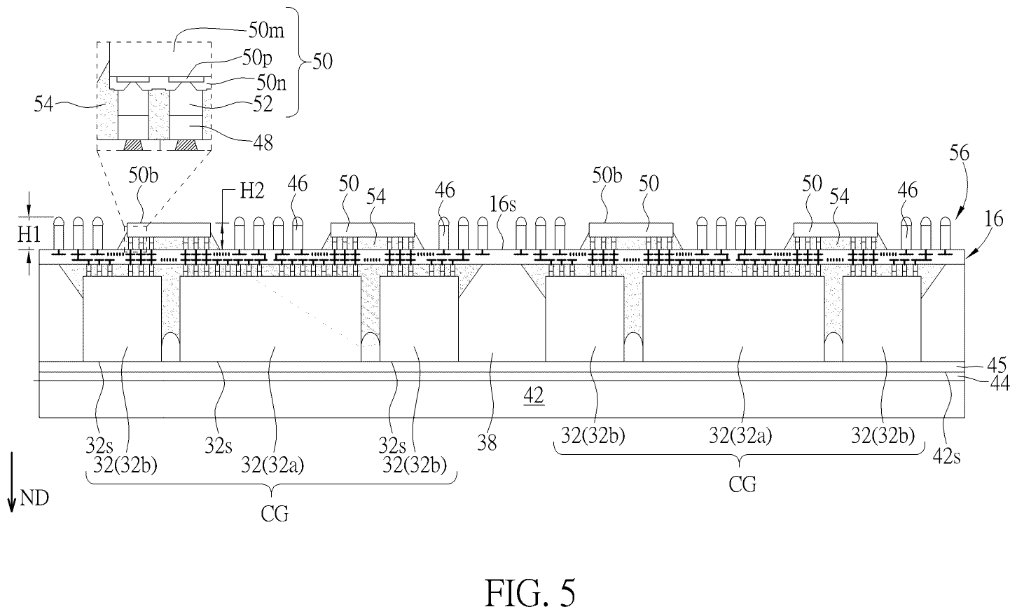

As shown in FIG. 5, after the conductive pillars 46 are formed, at least one chip 50 may be disposed on the redistribution layer 16 in a face-down way through a flip-chip bonding process. In other words, the chip 50 may have a plurality of conductive bumps 52, and during bonding, the chip 50 is bonded to the redistribution layer 16 in a way of the conductive bumps 52 facing the redistribution layer 16 and a back surface 50b of the chip 50 facing upward. One of the conductive bumps 52 may include, for example, a multi-layer structure. The conductive bump 52 may, for example, include copper, nickel, tin, silver, other suitable materials, alloys of at least two thereof, or a combination thereof, but not limited thereto. In the embodiment shown in FIG. 5, the chip 50 may further include, for example, a body portion 50m, a plurality of pads 50p, and an insulating layer 50n, in which the pads 50p are disposed on the body portion 50m, and the insulating layer 50n is disposed on the pads 50p and the body portion 50m and may have a plurality of openings respectively exposing the corresponding pads 50p. The conductive bumps 52 are respectively formed on the corresponding pads 50p to facilitate bonding with the redistribution layer 16, but not limited thereto.

In the embodiment of FIG. 5, the conductive bumps 52 of the chip 50 may be bonded to the conductive pillars 48 disposed on the redistribution layer 16, so as to be coupled to the redistribution layer 16. Accordingly, a single chip 50 may be coupled to different chips 32 through the redistribution layer 16. A metal solder (not shown) may be further included between one of the conductive bumps 52 and the corresponding conductive pillar 48, for bonding the conductive bump 52 to the corresponding conductive pillar 48. The metal solder may include, for example, tin alloy solder or other suitable materials, but not limited thereto. The chip 50 may, for example, include a plurality of traces (not shown), in which a trace width and/or a space between two adjacent traces may be, for example, about 1 μm to 2 μm or sub-micron level, but not limited thereto. Since the trace pitch of the chip 50 may be less than the trace pitch of the redistribution layer 16, interconnection density between the chips 32 may be increased by coupling the chip 50 to different chips 32. Accordingly, signal transmission paths or signal transmission time between the chips 32 may be reduced, thereby improving signal transmission efficiency. In this case, the trace pitch of the redistribution layer 16 may not need to reach the fine pitch, so as to simplify the manufacturing complexity and reduce manufacturing cost. In addition, the number of layers of the redistribution layer 16 may be reduced using the chip 50 with reduced trace pitch, thereby mitigating warpage during the manufacturing process and reducing the manufacturing complexity.

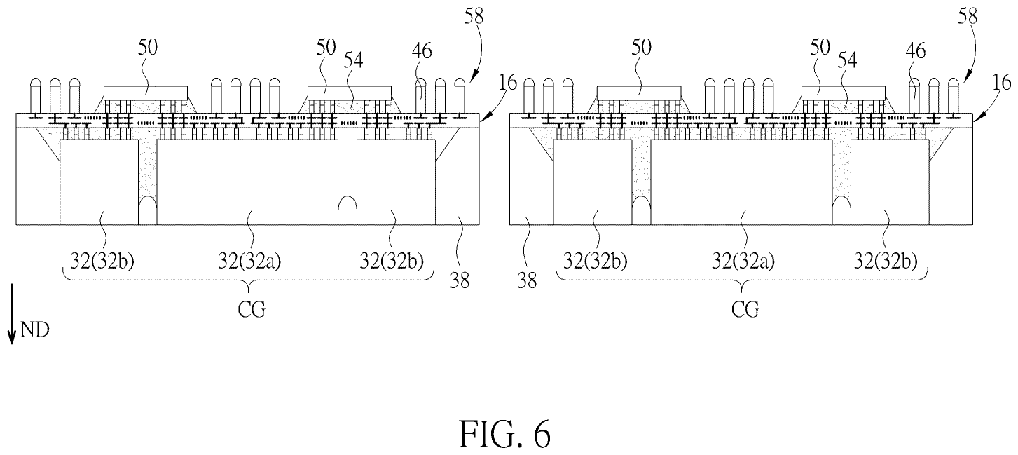

In some embodiments, a distance between two adjacent conductive bumps (such as the conductive bumps 34 shown in FIG. 2) of the chips 32 may be less than or equal to a distance between two adjacent conductive bumps 52 of the chip 50. When the distance between the conductive bumps 34 is equal to the distance between the conductive bumps 52, the traces of the redistribution layer 16 coupled to one of the conductive bumps 52 and the corresponding conductive bump 34 (such as one of the traces 24a and the corresponding trace 26a shown in FIG. 1) and one of the conductive bumps (such as the conductive bump 30 shown in FIG. 1) may be aligned with each other in a normal direction ND perpendicular to a upper surface 42s of the carrier 42, but not limited thereto. In some embodiments, the distance between two adjacent conductive bumps 52 may be less than a distance between two adjacent conductive pillars 46. The number of the chips 50 shown in FIG. 6 may be plural, but not limited thereto. The number of chip 50 may be determined, for example, according to the number of the chips 32 in the chip group CG and the number of the chip group CG.

The chip 50 may be, for example, a bridge chip, an active chip, a passive chip, or other suitable chips, wherein the active chip may include, for example, a HBM chip, a chiplet, or other suitable chips. The chip 50 and the chip 32 may be, for example, chips fabricated by different semiconductor process technology nodes and/or having different functionalities. For example, density of the active elements in the chip 50 is less than that of the active elements in the chip 32, or the chip 32 and the chip 50 may be the system chip fabricated by the wafer node of 3 nanometers (nm) and the memory chip fabricated by the wafer node of 65 nm, respectively, but not limited thereto. In some embodiments, a thickness of the chip 50 in the normal direction ND may be, for example, about 10 μm to 100 μm or more. In some embodiments, the chip 50 may optionally further include a passive element, such as a resistor, a capacitor, an inductor, or other similar elements.

As shown in FIG. 5, after the chip 50 is disposed, an underfill layer 54 may be formed between the chip 50 and the redistribution layer 16 to protect the bonding and coupling between the chip 50 and the redistribution layer 16, thereby forming a semi-finished structure 56. In the embodiment of FIG. 5, the underfill layer 54 may extend between two adjacent conductive bumps 52 in the chip 50. The material and forming manner of the underfill layer 54 may be, for example, the same as or similar to those of the underfill layer 36 and will not be described redundantly.

It should be noted that, as shown in FIG. 5, in order to prevent crack of the chip 50 caused by the back surface 50b of the chip 50 collided with a substrate during bonding the package structure to the substrate in a following step, a height H1 of one of the conductive pillars 46 may be greater than a height H2 of the back surface 50b of the chip 50 (i.e., a distance between the back surface 50b of the chip 50 and the surface 16s of the redistribution layer 16). Further, the height H1 of the conductive pillar 46 may still be higher than the height H2 of the back surface 50b of the chip 50 after reflow. For example, the difference between the height H1 and the height H2 may be greater than or equal to 50 μm, but not limited thereto.

As shown in FIG. 6, after the semi-finished structure 56 is formed, the carrier 42 may be removed. The manner of removing the carrier 12 may include, for example, irradiating the release layer 44 with light to reduce the adhesion of the release layer 44, thereby removing the carrier 42, but not limited thereto. Then, a singulation process may be performed on the semi-finished structure 56 to form at least one package structure 58. In the embodiment of FIG. 6, the semi-finished structure 56 may include at least two chip groups CG, so that the singulation process may separate different chip groups CG from each other and separate the chips 50 and the conductive pillars 46 corresponding to different chip groups CG from each other, so as to form at least two package structures 58. The singulation process may, for example, include a dicing process or other suitable processes.

As shown in FIG. 7, after the singulation process, the package structure 58 may be turned upside down, and the conductive pillars 46 of the package structure 58 may be disposed on the substrate 60. The conductive pillars 46 may couple and bond the package structure 58 to the substrate 60. Then, an underfill layer 62 is formed between two adjacent conductive pillars 46 of the package structure 58 and between the conductive pillars 46 and the chip 50 to form the package device 1. It should be noted that, since only one underfill layer 62 needs to be disposed between the redistribution layer 16 and the substrate 60, the manufacturing steps and the manufacturing complexity of the package device 1 may be simplified. The substrate 60 may include, for example, a package substrate, a circuit board, or other suitable substrate. The underfill layer 62 may extend to sidewalls of the encapsulant 38 of the package structure 58 and may strengthen the bonding between the package structure 58 and the substrate 60. In the embodiment of FIG. 7, the underfill layer 62 may, for example, extend between the substrate 60 and the chip 50. The material and forming manner of the underfill layer 62 may be, for example, the same as or similar to the material and forming manner of the underfill layer 36 or the underfill layer 54 and are not described herein again.

In some embodiments, a stiffener 64 may be disposed on the substrate 60, and the stiffener 64 may, for example, surround the package structure 58 and be spaced apart from the underfill layer 62. The stiffener 64 may include metal, for example. In some embodiments, solder balls 66 may be optionally disposed under the substrate 60 to facilitate coupling and bonding of the package element 1 with other elements, but not limited thereto.

It should be noted that, in the package device 1 of FIG. 7, since the redistribution layer 16 is disposed between the chips 32 and the conductive pillars 46 and between the chips 32 and the chip 50, the chips 32 may be simultaneously coupled to the conductive pillars 46 and the pads of the chip 50 that have different pitches, and the chips 32 and the chip 50 having different wafer nodes and/or different chips 32 having different wafer nodes may be integrated in the same package structure 58, such that higher density of the input/output pads may be achieved. For example, when the pitch of the conductive pillars 46 is different from the pitch of the pads of the chips 32, at least one conductive pillar 46 is separated from the chips 32 in a top view. Furthermore, through stacking and coupling the chips 32 with the chip 50 in the normal direction ND, the signal transmission paths between the chip 32 and the chip 50 and between different chips 32 can be shortened to improve signal transmission efficiency between the chips 32 and the chip 50. In the present disclosure, the top view direction of the package device is an opposite direction of the normal direction ND. Also, the chip 50 and the conductive pillars 46 are disposed side by side, so as to reduce the thickness and size of the package structure 58 and decrease the thickness and size of the package device 1. In addition, the chips 32 may be coupled to the substrate 60 through the redistribution layer 16 and the conductive pillars 46. As compared with being coupled to the substrate 60 through a silicon interposer, the manufacturing cost of the conductive pillars 46 and the chip 50 may be significant lower than that of the silicon interposer, thereby effectively decreasing the manufacturing cost of the package device 1.

The package device and the manufacturing method thereof are not limited to the above-mentioned embodiments and may have other embodiments. To simplify description, different embodiments in the following contents will use the same reference numerals to denote the same elements as the above-mentioned embodiments. To clearly illustrate different embodiments, differences between different embodiments will be described below, and repeated parts will not be detailed redundantly.

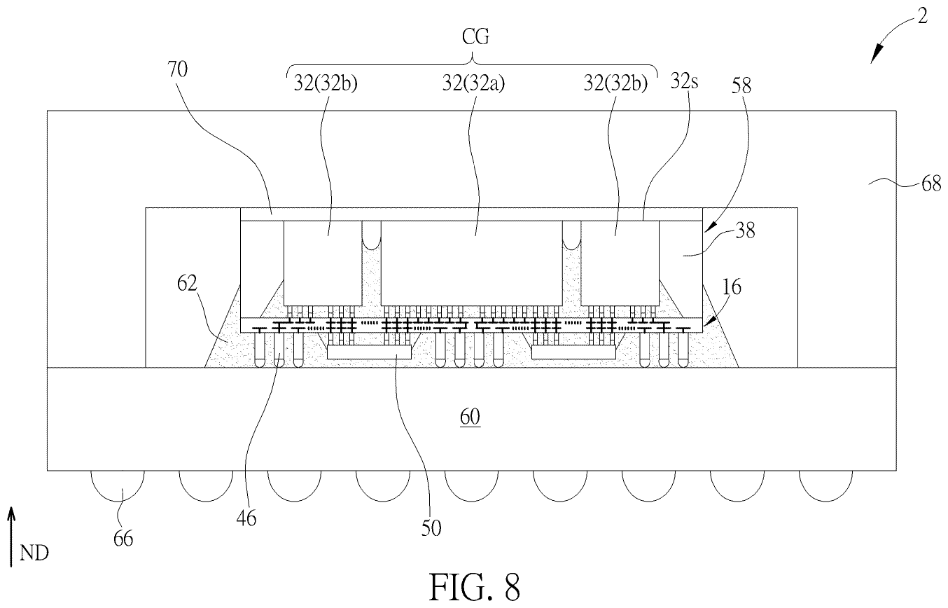

FIG. 8 schematically illustrates a cross-sectional view of a package device according to another embodiment of the present invention. As shown in FIG. 8, the package device 2 of this embodiment differs from the package element 1 shown in FIG. 7 in that the package device 2 may further include a metal cover 68 that replaces the stiffener 64 of FIG. 7 and is disposed on the package structure 58 and the substrate 60. The metal cover 68 may cover and surround the package structure 58 to protect the package structure 58, for example. The metal cover 68 may be, for example, an integrally formed structure, but not limited thereto. In some embodiments, the package device 2 may optionally further include a thermal grease 70 disposed on the back surfaces 32s of the chips 32. The thermal grease 70 may, for example, directly contact the chips 32 and the metal cover 68 to facilitate heat dissipation of the chips 32. The thermal grease 70 may, for example, be coated on the back surfaces of the chips 32 before disposing the metal cover 68, but not limited thereto.

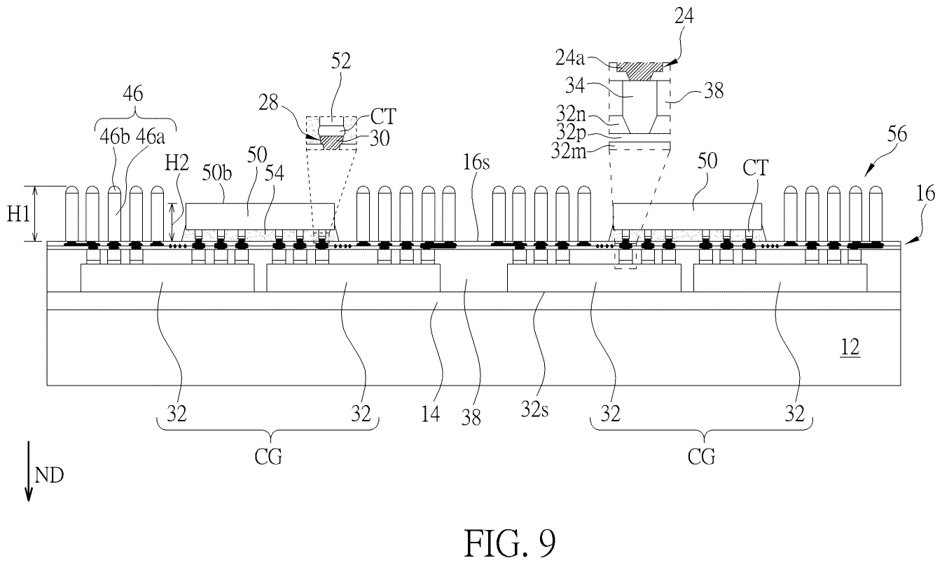

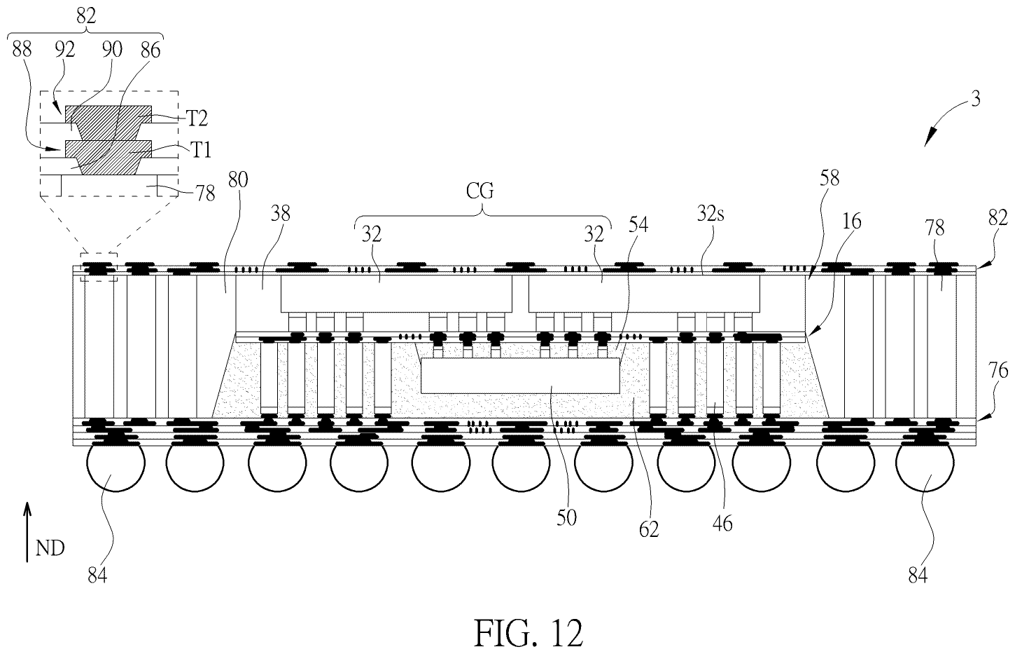

Please refer to FIG. 9 to FIG. 12. FIG. 9 to FIG. 12 schematically illustrate a manufacturing method of a package device according to a third embodiment of the present invention, wherein FIG. 12 is a schematic cross-sectional diagram of the package device according to the third embodiment of the present invention. The structures shown in FIG. 9 to FIG. 11 are partial structures in different steps of the manufacturing method of the package device, respectively, and may omit parts of layers or elements. As shown in FIG. 9 to FIG. 12, a difference between the manufacturing method of the package device 3 of this embodiment and the above embodiment is that the manufacturing method further a includes forming redistribution layer 76; forming a plurality of conductive pillars 78 on the redistribution layer 76; disposing the package structure 58 on the redistribution layer 76; forming an encapsulant 80 on the redistribution layer 76; and forming a redistribution layer 82 on the conductive pillars 78 and the package structure 58. The manufacturing method of the package element 3 of this embodiment is further detailed below.

As shown in FIG. 9, another difference between the step of providing the package structure 58 of this embodiment and the above embodiment is that this embodiment adopts a chip first process. Specifically, the step of providing the package structure 58 in this embodiment may include the following steps. First, the carrier 12 is provided first, and then at least two chips 32 are disposed on the carrier 12, wherein the chips 32 are disposed on and attached to the carrier 12 in a way that the conductive bumps 34 face up. The step of providing the carrier 12 in this embodiment may be the same as the step of providing the carrier 12 in FIG. 1, and may include forming the release layer 14 on the carrier 12.

Then, the encapsulant 38 is formed on the carrier 12 and the chips 32, wherein the encapsulant 38 at least surrounds the chips 32. In the step of forming the encapsulant 38, the encapsulant 38 is formed between the chips 32 and on the insulating layers 32n and the conductive bumps 34 of the chips 32 through the molding process, and then remove the encapsulant 38 located on the conductive bumps 34 through the thinning process to expose the conductive bumps 34, thereby facilitating coupling with the redistribution layer 16 formed in subsequent step.

After the encapsulant 38 is formed, the redistribution layer 16 is formed on the encapsulant 38 and the conductive bumps 34. Then, the conductive pillars 46 arranged side by side are formed on the redistribution layer 16. The method of forming the redistribution layer 16 and the conductive pillars 46 may be the same as or similar to the above embodiments, so the above embodiments may be referred to, and they will not be repeated here. In this embodiment, since the encapsulant 38 only exposes the conductive bumps 34 and covers the insulating layers 32n of the chips 32, a portion of the encapsulant 38 is located between the chips 32 and the redistribution layer 16 after the redistribution layer 16 is formed.

After the conductive pillars 46 are formed, at least one chip 50 is disposed on the redistribution layer 16, wherein the chip 50 is disposed on and attached to the redistribution layer 16 through the flip chip bonding process in a way that the conductive bumps 52 face down. Then, the underfill layer 54 is formed between the chip 50 and the redistribution layer 16 to protect the bonding and coupling between the chip 50 and the redistribution layer 16, thereby forming the semi-finished structure 56. In this embodiment, the chip 50 is bonded to the redistribution layer 16 through conductive terminals CT, but not limited thereto. The conductive terminal CT may include, for example, solder ball or other suitable conductive bonding materials. In some embodiments, the method of bonding the chip 50 to the redistribution layer 16 in FIG. 9 may alternatively be the same as that in FIG. 5.

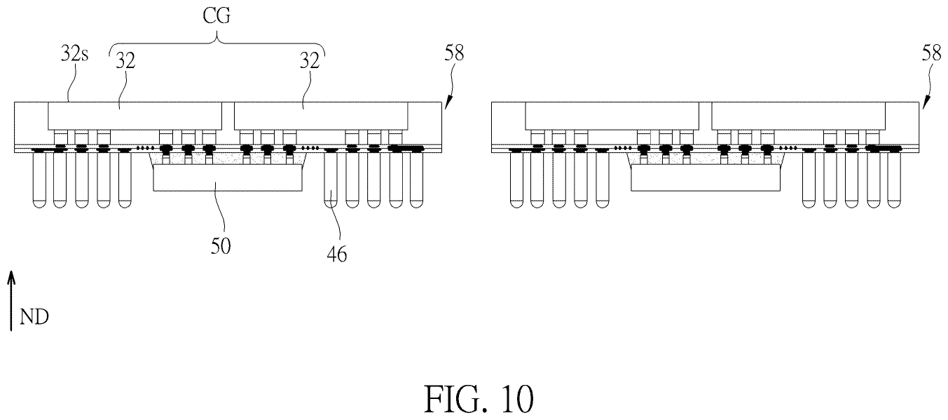

As shown in FIG. 10, the carrier 12 is removed after the semi-finished structure 56 is removed. The method of removing the carrier 12 may be the same as the above embodiment, so the above embodiment may be referred to, and it will not be repeated here. After that, the semi-finished structure 56 can be turned upside down, and then a singulation process is performed to form at least one package structure 58. Alternatively, the package structure 58 may be turned upside down after singulating the semi-finished structure 56. The singulation process may separate different chip groups CG from each other and separate the chips 50 and the conductive pillars 46 corresponding to the different chip groups CG 50 from each other to form at least two package structures 58. The singulation process may include, for example, the dicing process or other suitable processes. In some embodiments, the method of forming the package structure 58 may alternatively adopt the method in the first embodiment described above, but not limited thereto.

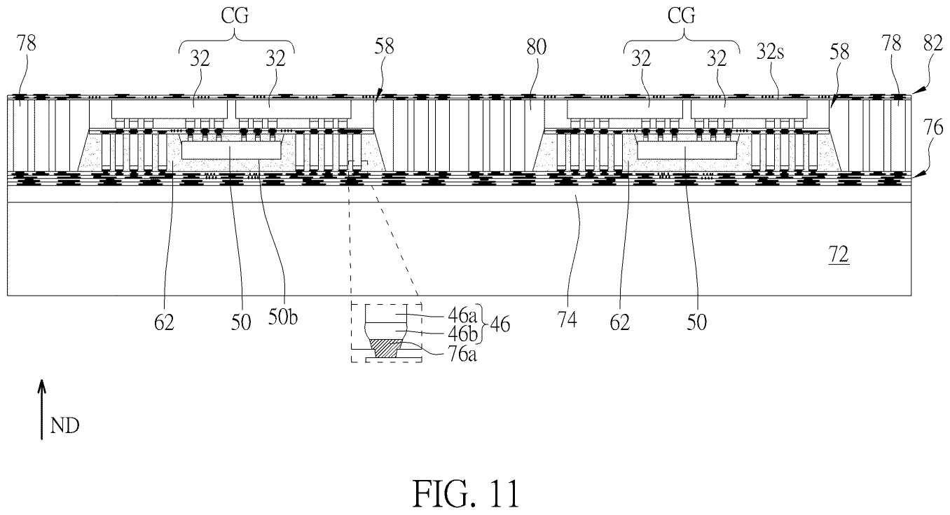

As shown in FIG. 11, another carrier 72 is provided, wherein a release layer 74 may be provided on the carrier 72. Then, the redistribution layer 76 is formed on the release layer 74. The carrier 72 and the release layer 74 may be similar or identical to the carrier 12 and the release layer 14 of the above embodiment, respectively, and the method of forming the redistribution layer 76 may be similar or identical to that of forming the redistribution layer 16, so it will not be repeated here. The redistribution layer 76 may include a plurality of pads 76a used to be bonded to the package structure 58, and a distance between center points of adjacent two of the pads 76a of the redistribution layer 76 may be, for example, greater than 40 mm.

After the redistribution layer 76 is formed, a plurality of conductive pillars 78 is formed on the redistribution layer 76. For example, the conductive pillar 78 may be copper pillar or other suitable columnar conductive structure with flat upper and lower surfaces used for signal connections inside the package structure 58 or package device (e.g., the package device 3). Then, the package structure 58 is bonded to the redistribution layer 76 in a way that the conductive pillars face down. In other words, the package structure 58 and the conductive pillars 78 are disposed side by side on the redistribution layer 76. The method of forming the conductive pillars 78 may be similar or identical to that of forming the pillar portions 46a of the conductive pillars 46, and the method of bonding the package structure 58 to the redistribution layer 76 may be the same as that of bonding the package structure 58 to the substrate 60 in FIG. 7, so the above embodiment may be referred to, and it will not be repeated here. Since the steps of providing the carrier 72, forming the redistribution layer 76, and forming the conductive pillars 78 do not interfere with the step of providing the package structure 58, any of the steps of providing the carrier 72, forming the redistribution layer 76, and forming the conductive pillars 78 may be performed before, after, or during the step of forming the package structure 58.

After the conductive pillars 46 are bonded to the redistribution layer 76, the underfill layer 62 is formed between the package structure 58 and the redistribution layer 76 to improve the adhesion between the package structure 58 and the redistribution layer 76, wherein the underfill layer 62 may extend to be between two adjacent conductive pillars 46 and between one of the conductive pillars 46 and the chip 50. The method of forming the underfill layer 62 may be similar or identical to that of the underfill layer 54, so it will not be repeated here. The material of the underfill layer 62 may be the same as that of the underfill layer 54 to mitigate difference between the coefficients of thermal expansion and/or improve process stability or mechanical strength. In some embodiments, the underfill layer 62 and the underfill layer 54 may include different materials. Since there may be a sufficient distance between the conductive pillars 78 and the package structure 58 in a horizontal direction parallel to an upper surface of the carrier 72 (or perpendicular to the normal direction ND), the underfill layer 62 may be separated from the conductive pillars 78. Further, the height H1 of the conductive pillar 46 may be greater than the height H2 between the back surface 50b of the chip 50 and the redistribution layer 16, as shown in FIG. 9, so that when the package structure 58 is bonded to the redistribution layer 76, the chip 50 will not collide with the redistribution layer 76, thereby avoiding the chip 50 being damaged, and the underfill layer 62 may separate the redistribution layer 76 from the chip 50.

As shown in FIG. 11, after the underfill layer 62 is formed, an encapsulant 80 is formed on the redistribution layer 76, the conductive pillars 78, and the package structure 58, wherein the encapsulant 80 may be located between two adjacent conductive pillars 78 and between one of the conductive pillars 78 and the package structure 58. Then, the redistribution layer 82 is formed on the encapsulant 80 and the conductive pillars 78. In the step of forming the encapsulant 80, the encapsulant 80 may be formed by the molding process, and the encapsulant 80 located on the conductive pillars 78 is removed to expose the conductive pillars 78 by the thinning process, thereby facilitating coupling with the redistribution layer 82. For example, an upper surface of the encapsulant 80 may be aligned with an upper surface of the conductive pillar 78. In the normal direction ND of the back surface 32s of the chip 32, a height of the conductive pillar 78 may be greater than or equal to a height of the package structure 58. For example, the height of the conductive pillar 78 may be greater than the height of the conductive pillar 46. In this embodiment, when the height of the conductive pillar 78 is equal to the height of the package structure 58, the back surfaces 32s of the chips 32 of the package structure 58 may be exposed to facilitate heat dissipation, but not limited to. In some embodiments, the encapsulant 80 may further cover the back surfaces 32s of the chips 32. The method of forming the redistribution layer 82 may be similar or identical to that of forming the redistribution layer 16, so it will not be repeated here.

As shown in FIG. 12, after the redistribution layer 82 is formed, the carrier 72 and the release layer 74 are removed. The method of removing the carrier 72 may be the same as that of removing the carrier 12 described above, so the above embodiment may be referred to, and it will not be repeated here. Then, a plurality of conductive terminals 84 are formed on a surface of the redistribution layer 82 away from the package structure 58. Then, the singulation process is performed to form at least one package device 3. The conductive terminal 84 may include, for example, conductive bump or solder ball, wherein the conductive bump may be formed, for example, by the electroplating process, and the solder ball may be formed, for example, by a ball mounting process combined with a reflow process. The conductive bump may include, for example, copper, nickel, tin, silver, other suitable materials, alloys of at least two thereof, or a combination thereof. The solder ball may include, for example, tin alloy or other suitable materials. The singulation process may, for example, separate different package devices 3 including different package structures 58 to form at least two package devices 3. The single process may include, for example, a dicing process or other suitable processes.

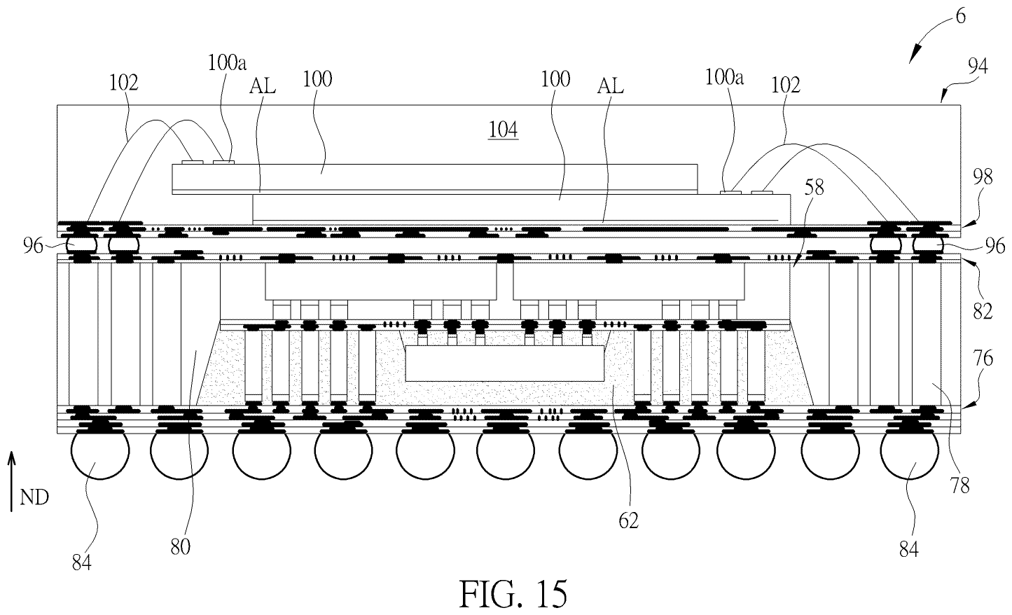

As shown in FIG. 12, the package device 3 may include the package structure 58, the redistribution layer 76, the underfill layer 62, a plurality of conductive pillars 78, the redistribution layer 82, and the encapsulant 80. The package structure 58 includes the conductive pillars 46 disposed side by side, the redistribution layer 16, at least two chips 32, at least one chip 50, and the encapsulant 38. The redistribution layer 16 is disposed on the conductive pillars 46, the chips 32 are disposed on the redistribution layer 16, and the chip 50 is disposed under the redistribution layer 16, wherein the chips 32 are coupled to chip 50 through the redistribution layer 16. The encapsulant 38 is disposed on the redistribution layer 16 and surrounds the chips 32. The package structure 58 is disposed on the redistribution layer 76, and the chip 50 is located between the redistribution layer 16 and the redistribution layer 76. The underfill layer 62 is disposed between two adjacent conductive pillars 46 and the conductive pillar 46 and the chip 50. The conductive pillars 78 and the package structure 58 are arranged side by side on the redistribution layer 76. The redistribution layer 82 is disposed on the package structure 58 and the conductive pillars 78, and the encapsulant 80 is disposed between the redistribution layer 76 and the redistribution layer 82 and surrounds the package structure 58 and the conductive pillars 78. In other words, the t redistribution layer 76 and the redistribution layer 82 may be located on the upper and lower sides of the package structure 58 respectively, and the redistribution layer 76 may be coupled to the redistribution layer 82 through the conductive pillars 78, so that the package device 3 not only can couple the package structure 58 to other elements through the redistribution layer 76 and the conductive terminals 84, but also can be bonded and coupled to another element through the redistribution layer 82. For example, the package device 3 may be bonded and coupled to other package structure (e.g., the package structure shown in FIG. 15) by the redistribution layer 82 to enhance performance or functionality of the package device 3. Compared to using copper shell ball to couple different organic circuit substrates of the prior art, the redistribution layer 82 and the redistribution layer 76 of this embodiment may satisfy the requirements of the chips 32 or the chip 50 having higher density of input/output pads.

It should be noted that as functionality of the chip increases, the chip requires more input/output pads, which needs to shrink pad size and pad pitch in the case that the chip size is not changed, or to increase chip size. However, the conventional organic circuit substrate cannot provide smaller pad pitch, which affects chip assembly. Also, to increase the chip size results in higher wafer cost. Therefore, when large-sized chip is split into multiple chiplets to reduce the wafer cost, the package device 3 of this embodiment may provide smaller pad pitch to meet the pad pitch requirements of multiple chiplets.

Furthermore, in FIG. 12, the redistribution layer 82 of this embodiment including the dielectric layer 86 and the conductive layer 88 closest to the chips 32 and the dielectric layer 90 and the conductive layer 92 farthest from the chips 32 is taken as an example, but the numbers of the dielectric layers and the conductive layers of the redistribution layer 82 are not limited thereto. The conductive layer 88 may include a plurality of traces T1 respectively coupled to the corresponding conductive pillars 78. The conductive layer 92 may further include a plurality of pads T2 respectively coupled to the corresponding traces T1 and exposed to the upper surface of the redistribution layer 82. Accordingly, the pads T2 are coupled to the redistribution layer 76 through the traces T1 and the conductive pillars 78, and the pads T2 may be further bonded and coupled to other elements. In this embodiment, at least one trace T1 and at least one pad T2 may overlap the package structure 58 or the chip 32 in the normal direction ND, which is opposite to the top view direction of the package device 3, and the trace T1 overlapping the package structure 58 may be separated from the chip 32 by the dielectric layer 86, so that part of the traces T1 and part of the pads T2 may be located on the package structure 58, thereby making full use of other space of the redistribution layer 82, but not limited thereto. In some embodiments, the traces T1 and the pads T2 may not overlap the package structure 58 or the chips 32.

In this embodiment, the pads of the chips 32 within the package structure 58 may face the redistribution layer 76, and the chips 32 and the chip 50 may be coupled to the redistribution layer 76 through the conductive pillars 46. To meet the requirements of increasing number of input/output pads of the chips 32 and the chip 50, the redistribution layer 76 may have a certain thickness, for example, greater than the thickness of the redistribution layer 82. The thickness of the redistribution layer 76 may, for instance, be in the range from 130 μm to 150 μm, while the thickness of the redistribution layer 82 may be approximately 100 μm.

It should be noted that, in the package device 3 of this embodiment, the chips 32 may overlap the chip 50 along the normal direction ND, and the package device 3 may overlap other package structures along the normal direction ND. As a result, not only the signal transmission paths between the chips 32 and the chip 50 and between the chips 32 can be shortened, but also the signal transmission path between package device 3 and other package structures can be reduced, thereby enhancing the performance of package device 3. Furthermore, the chip 50 may be arranged side by side with the conductive pillars 46, and package structure 58 may further be arranged side by side with the conductive pillars 78. Hence, this configuration can further reduce the overall thickness and size of package device 3, making it more suitable for applications such as mobile application processors, wearable devices, or other appropriate uses.

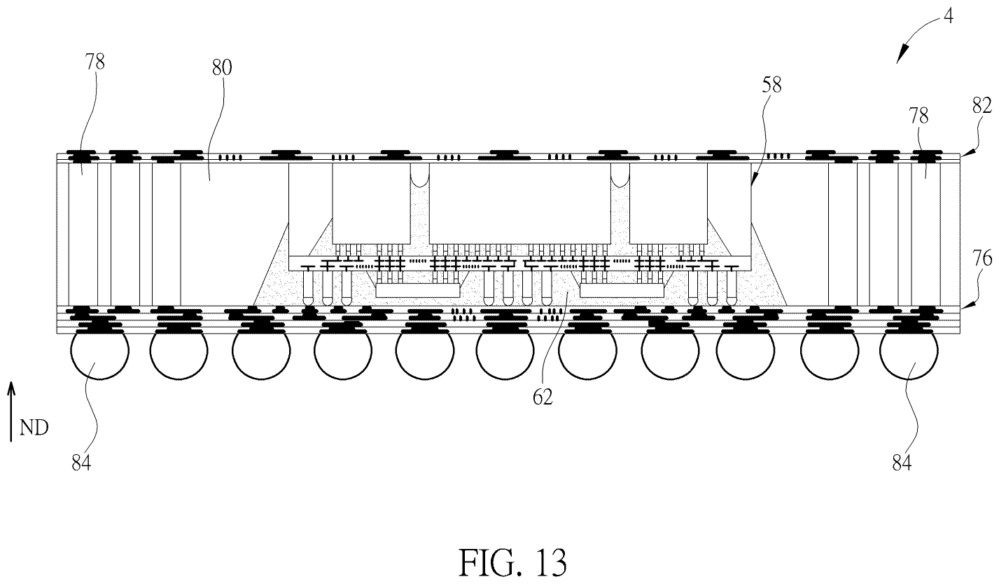

Please refer to FIG. 13, which schematically illustrates a cross-sectional view of a package device according to a fourth embodiment of the present invention. As shown in FIG. 13, the package device 4 of this embodiment differs from the package device 3 shown in FIG. 12 in that the package structure 58 in package device 4 may adopt the package structure 58 illustrated in FIG. 7. The other portions of package device 4 and its manufacturing method may be the same as those described in the above embodiments and are therefore not repeated here.

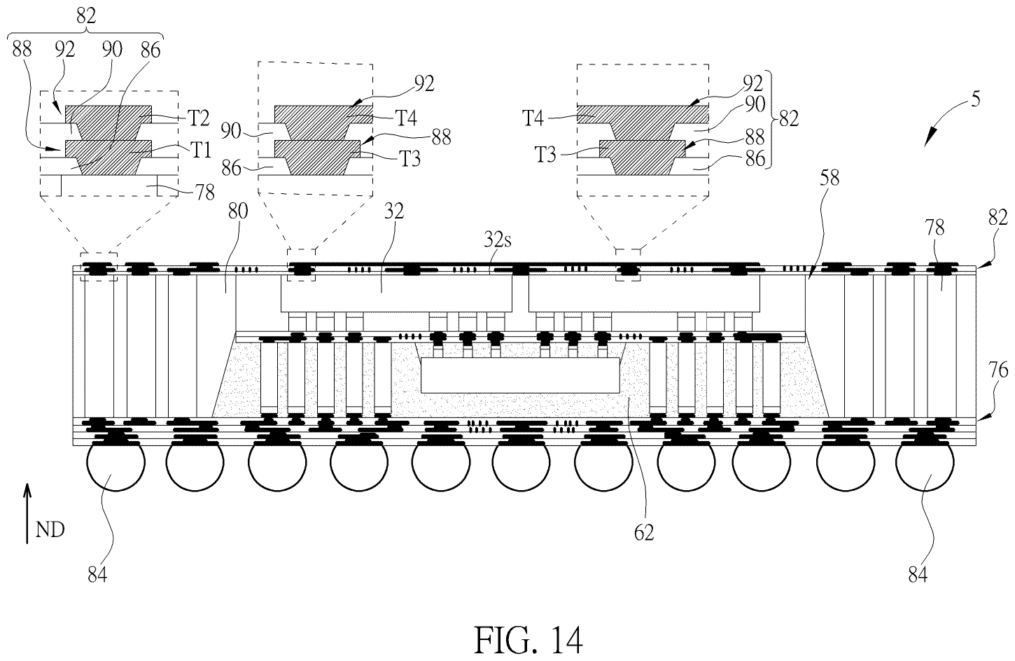

Please refer to FIG. 14, which schematically illustrates a cross-sectional view of a package device according to a fifth embodiment of the present invention. As shown in FIG. 14, the package device 5 of this embodiment differs from the package device 3 shown in FIG. 12 in that the redistribution layer 82 may include at least two traces T3 contacting the back surfaces 32s of the chips 32 away from the redistribution layer 16, such that heat of the chips 32 is able to be dissipated through the traces T3. Specifically, the dielectric layer 86 of the redistribution layer 82 may be in direct contact with the back surfaces 32s of chips 32 and may include a plurality of through holes. The conductive layer 88 may include a plurality of traces T3, wherein two of the traces T3 may respectively contact different chips 32 through different through holes of the dielectric layer 86, thereby providing separate thermal dissipation paths for different chips 32. In some embodiments, at least one of the traces T3 may be simultaneously disposed in different through holes of the dielectric layer 86 and contact different chips 32 to enhance heat dissipation, but not limited thereto.

In this embodiment, the dielectric layer 90 may further have a plurality of through holes, and the conductive layer 92 may include at least one heat dissipation pad T4 coupled to the traces T3 in contact with different chips 32. The conductive layer 92 is a conductive layer of the redistribution layer 82 farthest from the chips 32 and is exposed, so that the heat dissipation pad T4 can be used to improve the heat dissipation effect of the chips 32. In FIG. 14, the heat dissipation pad T4 may extend into different through holes to be connected to different traces T3, so that the heat dissipation pad T4 may overlap different traces T3 in the normal direction ND (or the top view direction), or a width of the heat dissipation pad T4 in the horizontal direction may be greater than a width of the chip 32 in the horizontal direction, but not limited thereto.

In this embodiment, the trace T3 may, for example, be a dummy trace, and in this case, the trace T3 may be separated from the traces T1 and electrically insulated from the traces T1. The heat dissipation pad T4 may be, for example, a dummy metal sheet separated from the pads T2 and electrically insulated from the pads T2. In other words, the redistribution layer 82 of this embodiment can be used not only to couple the elements thereon to the redistribution layer 76 but also to provide heat dissipation for the chips 32. The trace T3 disclosed here is not limited to the dummy element, and in some embodiments, the trace T3 may alternatively be the trace T1 coupled to the conductive pillar 78.

Please refer to FIG. 15, which schematically illustrates a cross-sectional view of a package device according to a sixth embodiment of the present invention. As shown in FIG. 15, the package device 6 of this embodiment differs from the package device 3 of FIG. 12 in that the package device 6 may further include a package structure 94 bonded to the redistribution layer 82. For example, the package device 6 may further include a plurality of conductive terminals 96, and the package structure 94 may be bonded and coupled to the redistribution layer 82 through the conductive terminals 96.

In this embodiment, the package structure 94 may include a redistribution layer 98, a plurality of chips 100, a plurality of conductive wires 102, and an encapsulant 104. The chips 100 may be sequentially stacked on the redistribution layer 98 through the adhesive layers AL, and the pads 100a of the chips 100 may be coupled to the redistribution layer 98 through the conductive wires 102, respectively. The encapsulant 104 are disposed on the chips 100 and cover the conductive wires 102 to protect the chips 100, conductive wires 102, and the redistribution layer 98. The chip 100 may include, for example, DRAM chip, SRAM chip, HBM chip, other suitable memory chip, or other suitable chips. In some embodiments, the package structure 94 may be, for example, alternatively replaced with logic chip, passive elements, optical element, or other suitable elements.

In summary, in the package device of the present invention, the chip is used to couple different chips, so that the interconnection density between the chips may be increased, thereby improving the signal transmission efficiency. Moreover, since the height of the conductive pillars arranged side by side with the chip may be greater than the height of the back surface of the chip, when the package structure is bonded to the substrate, the chip may be prevented from colliding with the substrate, thereby reducing crack of the chip. In addition, the redistribution layer may be disposed between the chips and the conductive pillars and between the chips and the chip, so that the chips may be coupled to the conductive pillars and the pads of the chip that have different pitches through the redistribution layer and may be coupled to the substrate through the conductive pillars. Accordingly, the manufacturing cost of the package device may be reduced. In addition, by disposing two redistribution layers on the upper and lower sides of the package structure and coupling them through the conductive pillars, the package structure can be coupled to not only other elements but also other package structures to increase the performance or functionality of the package device, such that the chips with higher density of the input/output pads can be used in the package device.

Those skilled in the art will readily observe that numerous modifications and alterations of the device and method may be made while retaining the teachings of the invention. Accordingly, the above disclosure should be construed as limited only by the metes and bounds of the appended claims

What is claimed is:

1. A package device, comprising:
a package structure comprising:
a plurality of first conductive pillars disposed side by side;
a first redistribution layer disposed on the first conductive pillars;
at least two first chips disposed on the first redistribution layer;
at least one second chip disposed under the first redistribution layer, wherein the second chip is coupled to the first chips through the first redistribution layer; and
a first encapsulant disposed on the first redistribution layer and surrounding the first chips;
a second redistribution layer, wherein the package structure is disposed on the second redistribution layer, and the second chip is located between the first redistribution layer and the second redistribution layer;
a first underfill layer disposed between adjacent two of the first conductive pillars and between one of the first conductive pillars and the second chip;
a plurality of second conductive pillars disposed on the second redistribution layer and side by side with the package structure;
a third redistribution layer disposed on the package structure and the second conductive pillars; and
a second encapsulant disposed between the second redistribution layer and the third redistribution layer and surrounding the package structure and the second conductive pillars.

2. The package device according to claim 1, wherein the third redistribution layer comprises at least two traces contacting back surfaces of the first chips away from the first redistribution layer, respectively.

3. The package device according to claim 2, wherein the third redistribution layer comprises a conductive layer farthest from the first chips, and the conductive layer comprises a heat dissipation pad coupled to the traces.

4. The package device according to claim 3, wherein the heat dissipation pad overlaps the traces in a top view direction.

5. The package device according to claim 3, wherein the second redistribution layer is separated from the second chip by the first underfill layer.

6. The package device according to claim 1, further comprising a second underfill layer disposed between the second chip and the first redistribution layer.

7. The package device according to claim 1, wherein the second chip overlaps the first chips in a top view direction.

8. The package device according to claim 1, wherein one of the first conductive pillars is separated from the first chips in a top view.

9. The package device according to claim 1, wherein the first encapsulant is disposed between the first chips and the first redistribution layer.

10. The package device according to claim 1, wherein a height of each of the second conductive pillars is greater than a height of each of the first conductive pillars.

11. A manufacturing method of a package device, comprising:
providing a package structure, wherein the package structure comprises:
a plurality of first conductive pillars disposed side by side;
a first redistribution layer disposed on the first conductive pillars;
at least two first chips disposed on the first redistribution layer;
at least one second chip disposed under the first redistribution layer, wherein the second chip is coupled to the first chips through the first redistribution layer; and
a first encapsulant disposed on the first redistribution layer and surrounding the first chips;
forming a second redistribution layer on a first carrier;
forming a plurality of second conductive pillars on the second redistribution layer;
disposing the package structure on the second redistribution layer;
forming a second encapsulant on the second redistribution layer, wherein the second encapsulant surrounds the package structure and the second conductive pillars;
forming a third redistribution layer on the second conductive pillars and the package structure; and
removing the first carrier.

12. The manufacturing method of the package device according to claim 11, wherein after disposing the package structure on the second redistribution layer, the manufacturing method further comprises forming a first underfill layer between the first conductive pillars and between one of the first conductive pillars and the second chip.

13. The manufacturing method of the package device according to claim 12, wherein the second redistribution layer is separated from the second chip by the first underfill layer.

14. The manufacturing method of the package device according to claim 11, wherein providing the package structure comprises forming a second underfill layer between the second chip and the first redistribution layer.

15. The manufacturing method of the package device according to claim 11, wherein providing the package structure comprises:
disposing the first chips on a second carrier;
forming the first encapsulant on the second carrier and the first chips;
forming the first redistribution layer on the first encapsulant;
forming the first conductive pillars on the first redistribution layer;
disposing the second chip on the first redistribution layer; and
removing the second carrier.

16. The manufacturing method of the package device according to claim 11, wherein providing the package structure comprises:
forming a first redistribution layer on a second carrier;
disposing the first chips on the first redistribution layer;
forming the first encapsulant on the first redistribution layer;
transferring the first redistribution layer, the first chips, and the first encapsulant to a third carrier to expose a surface of the first redistribution layer away from the first chips;
forming the first conductive pillars on the surface of the first redistribution layer away from the first chips;
disposing the second chip on the first redistribution layer; and
removing the third carrier.

17. The manufacturing method of the package device according to claim 11, wherein the third redistribution layer comprises at least two traces contacting back surfaces of the first chips away from the first redistribution layer, respectively.

18. The manufacturing method of the package device according to claim 17, wherein the third redistribution layer comprises a conductive layer farthest from the first chips, and the conductive layer comprises a heat dissipation pad coupled to the traces.

19. The manufacturing method of the package device according to claim 18, wherein the heat dissipation pad overlaps the traces in a top view direction.

20. The manufacturing method of the package device according to claim 11, wherein the second chip overlaps the first chips in a top view direction.
